(19) United States
(12) Patent Application Publication
(10) Pub. No.: US 2024/0426021 A1
(43) Pub. Date: Dec. 26, 2024

(54) SYSTEM AND METHOD FOR GROWTH OF QUASI-PHASE MATCHED STRONTIUM TETRABORATE AND LITHIUM TRIBORATE CRYSTALS FOR FREQUENCY CONVERSION

(71) Applicant: KLA Corporation, Milpitas, CA (US)

(72) Inventors: Kelly Mauser, Santa Clara, CA (US); Yung-Ho Alex Chuang, Cupertino, CA (US); Baigang Zhang, San Jose, CA (US); Xuefeng Liu, San Jose, CA (US); John Fielden, Los Altos, CA (US); Elena Loginova Casey, Morgan Hill, CA (US)

(21) Appl. No.: 18/588,822

(22) Filed: Feb. 27, 2024

Related U.S. Application Data
(60) Provisional application No. 63/521,880, filed on Jun. 20, 2023.

(51) Int. Cl. C30B 17/00; C30B 29/10; C30B 33/06; C30B 35/00; G02F 1/35; G02F 1/355; G02F 1/37

(52) U.S. Cl. CPC C30B 17/00; C30B 29/10; C30B 33/06; C30B 35/002; G02F 1/3501; G02F 1/3548; G02F 1/3551; G02F 1/37

(57) ABSTRACT

A method for growing a periodically-poled nonlinear crystal may include placing a seed crystal into a melt to form a seed crystal melt mixture, where the seed crystal may include at least one of strontium tetraborate (SBO) or lithium triborate (LBO), and where the melt includes at least one of a mixture of Sr, B, and O or a mixture of Li, B, and O. The method may further include heating the seed crystal melt mixture to a predetermined temperature until the periodically-poled nonlinear crystal forms.

### CROSS-REFERENCE TO RELATED APPLICATIONS

The present application claims the benefit under 35 U.S.C. § 119 (e) of U.S. Provisional Application Ser. No. 63/521,880, filed Jun. 20, 2023, which is incorporated herein by reference in the entirety.

### TECHNICAL FIELD

The present disclosure is related generally to a system and method for growth of nonlinear optical crystals and, more particularly, to a system and method for growth of periodically-poled nonlinear optical crystals.

### BACKGROUND

As semiconductor devices' dimensions shrink, the size of the smallest particle or pattern defect that can cause a device to fail also shrinks. Hence, a need arises for detecting smaller particles and defects on patterned and unpatterned semiconductor wafers and reticles. The intensity of light scattered by particles smaller than the wavelength of that light generally scales as a high power of the dimensions of that particle (e.g., the total scattered intensity of light from an isolated small spherical particle scales proportional to the sixth power of the diameter of the sphere and inversely proportional to the fourth power of the wavelength). Because of the increased intensity of the scattered light, shorter wavelengths will generally provide better sensitivity for detecting small particles and defects than longer wavelengths.

Since the intensity of light scattered from small particles and defects is generally very low, high illumination intensity is required to produce a signal that can be detected in a very short time. For example, average light source power levels of 1 W or more may be required. At these high average power levels, a high pulse repetition rate is desirable as the higher the repetition rate, the lower the energy per pulse and hence the lower the risk of damage to the system optics or the article being inspected. The illumination needs for inspection and metrology are often best met by continuous wave (CW) light sources. A CW light source has a constant power level, which avoids the peak power damage issues and allows for images or data to be acquired continuously. However, in many cases, mode-locked lasers (also called quasi-CW lasers) with repetition rates of about 50 MHz or higher can be useful because the high repetition rate means that the energy per pulse can be low enough to avoid damage for many metrology and inspection applications. The higher peak power of a mode locked laser as compared with a CW laser of the same average power level can allow more efficient and simpler frequency conversion.

Pulsed lasers for generating vacuum ultraviolet (VUV) light are known in the art. Prior-art lasers for generating light at 133 nm are well known (see for instance, G. W. Faris, and M. J. Dyer, “Two-photon excitation of neon at 133 nm”, Opt. Lett. 18, 382 (1993) and A. Tünnermann, C. Momma, K. Mossavi, C. Windolph, and B. Wellegehausen, “Generation of tunable short pulse VUV radiation by four-wave mixing in xenon with femtosecond KrF-excimer laser pulses”, IEEE J. Quantum Electron. 29, 1233 (1993)). Unfortunately, such lasers are not well suited to inspection applications because of their low laser pulse repetition rates and their use of toxic and corrosive gases in their lasing medium, which leads to high cost of ownership.

Solid-state deep ultraviolet (DUV) lasers are desirable due to their higher possible repetition rates, possibility for CW generation, and no need for toxic liquids or gases. There are a number of crystals that can be used for DUV frequency conversion. For example, beta barium borate (BBO) and cesium lithium borate (CLBO) crystals are common crystals for ultraviolet (UV) frequency conversion. Both materials have some capability for phase-matching UV light, but suffer from various disadvantages for high-power VUV frequency conversion. The damage threshold of BBO is relatively low when exposed to high-intensity DUV radiation. Furthermore, BBO is not transmissive below approximately 190 nm. CLBO can have a higher damage threshold than BBO, but is hygroscopic requiring great care during handling, processing, and operation. Additionally, CLBO shows increased absorption for wavelengths shorter than approximately 185 nm.

Other, less common, crystals have been explored for DUV frequency conversion. For example, potassium beryllium fluoroborate (KBBF) (KBe₂BO₃F₂) and others with beryllium fluoroborate (ABe₂BO₃F₂), where A=Na, K, Rb, Cs, TI, NH₄, have absorption edges between 147-155 nm, decent nonlinear coefficients, and large enough birefringence to make phase matching possible for 161-202 nm. Second harmonic generation of 200 nm light with 1.2 W power has been shown in KBBF, however, transparency begins to decrease for wavelengths shorter than 200 nm, making high power generation less likely for shorter wavelengths. Furthermore, the largest reported KBBF crystal grown is 3.7 mm (Wang, X. Y.; Yan, X.; Luo, S. Y.; Chen, C. T. “Flux Growth of Large KBBF Crystals by Localized Spontaneous Nucleation” J. Cryst. Growth, 318, 610-612 (2011)), which limits the application potential of this material.

Other DUV transmissive crystals exist, namely strontium beryllium borate (SBBO) (Sr₂Be₂B₂O₇), strontium pentafluoroaluminate (SrAIF₅), and boron phosphate (BPO₄), among others, but these crystals suffer from unstable crystal structures, difficulty with growth, toxic precursors, or need further development of growth methods and study of damage threshold and nonlinear processes.

Other nonlinear crystals transparent in the DUV do not have large enough birefringence to allow for birefringent phase matching in the DUV. However, quasi-phase matching is possible for many of these crystals. For example, barium magnesium fluoride (BaMgF₂) and strontium magnesium tetrafluoride (SrMgF₄) have high transmission down to about 125 nm and are ferroelectric and so can be periodically-poled for quasi-phase matching, but the nonlinear coefficients in these materials are too small to overcome losses from surface scattering or absorption in the material. Furthermore, periodic poling using the ferroelectric properties of a crystal do not always produce perfectly straight boundaries between poling domains, which is acceptable for infrared (IR) or visible quasi-phase-matching, but is detrimental in VUV/DUV quasi-phase-matching due to a smaller poling period caused by a greater mismatch in index of refraction between the shorter wavelengths involved, as found in Sellmeier index of refraction models of the transparent region of dielectric nonlinear frequency conversion crystals. There are currently no commercially available periodically-poled crystals for VUV/DUV frequency conversion of any dimension.

It is necessary to create VUV/DUV transmissive frequency conversion crystals grown with large enough dimensions (approximately 5-10 mm clear aperture) for a large enough conversion efficiency (requiring approximately tens to thousands of poling periods). However, unless the material is ferroelectric in the necessary dimension, a high quality growth method for periodically-poled VUV/DUV nonlinear bulk crystals does not currently exist.

Therefore, a need arises for a commercially scalable method to grow periodically-poled nonlinear crystals that generate DUV radiation near a wavelength of 120-200 nm and avoids many or all of the disadvantages of prior art crystals, and is suitable for use in systems configured for inspection of samples, configured for exposing a pattern into photoresist on a substrate, or configured for drilling, cutting or ablating materials including biological tissue.

### SUMMARY

A method for growing a periodically-poled nonlinear crystal is disclosed, in accordance with one or more embodiments of the present disclosure. In embodiments, the method includes placing a seed crystal into a melt to form a seed crystal melt mixture, where the seed crystal includes at least one of strontium tetraborate (SBO) or lithium triborate (LBO), where the melt includes at least one of a mixture of Sr, B, and O or a mixture of Li, B, and O. In embodiments, the method includes heating and cooling the seed crystal melt mixture to predetermined temperatures until the periodically-poled nonlinear crystal forms.

A periodically-poled nonlinear crystal is disclosed, in accordance with one or more embodiments of the present disclosure. In embodiments, the periodically-poled nonlinear crystal includes a plurality of crystal plates disposed in a stacked configuration, where the plurality of crystal plates include at least a first crystal plate and a second crystal plate, where the first crystal plate is adjacent to the second crystal plate, where the plurality of crystal plates include at least one of one or more strontium tetraborate (SBO) plates or one or more lithium triborate (LBO) plates, where the plurality of crystal plates are configured to form a periodic structure, where the periodic structure achieves quasi-phase-matching (QPM) of light.

An optical system is disclosed, in accordance with one or more embodiments of the present disclosure. In embodiments, the optical system includes an illumination source configured to generate illumination having a wavelength between 120 nm and 200 nm. In embodiments, the optical system includes an optical sub-system configured to direct the illumination from the illumination source onto a sample. In embodiments, the illumination source includes a first fundamental laser configured to generate a fundamental laser beam having a corresponding fundamental frequency and a fundamental wavelength between 720 nm and 800 nm. In embodiments, the illumination source includes two or more frequency doubling stages, the two or more frequency doubling stages including at least an intermediate frequency doubling stage and a final frequency doubling stage, where the intermediate frequency doubling stage is configured to receive the first fundamental frequency and generate a second harmonic light having a second harmonic frequency, where the final frequency doubling stage is configured to generate laser output light from the second harmonic light, where the final frequency doubling stage includes the nonlinear crystal configured to double a frequency of the second harmonic light, where the nonlinear crystal includes a plurality of crystal plates disposed in a stacked configuration such that each first SBO crystal plate is adjacent to at least one second crystal plate, where the plurality of crystal plates includes at least one of one or more strontium tetraborate (SBO) crystal plates or one or more lithium triborate (LBO) crystal plates, and where the plurality of crystal plates are cooperatively configured to form a periodic structure that achieves quasi-phase-matching (QPM) of the first fundamental frequency and the second harmonic frequency.

A laser assembly is disclosed, in accordance with one or more embodiments of the present disclosure. In embodiments, the laser assembly includes a first fundamental laser configured to generate a fundamental laser beam having a corresponding fundamental frequency and a fundamental wavelength between 720 nm and 800 nm. In embodiments, the laser assembly includes two or more frequency doubling stages, where the two or more frequency doubling stages includes at least an intermediate frequency doubling stage and a final frequency doubling stage, where the intermediate frequency doubling stage is configured to receive the first fundamental frequency and generate a second harmonic light having a second harmonic frequency, where the final frequency doubling stage is configured to generate laser output light from the second harmonic light, where the final frequency doubling stage includes the nonlinear crystal configured to double a frequency of the second harmonic light, where the nonlinear crystal includes a plurality of crystal plates disposed in a stacked configuration such that each first SBO crystal plate is adjacent to at least one second crystal plate, where the plurality of crystal plates includes at least one of one or more strontium tetraborate (SBO) crystal plates or one or more lithium triborate (LBO) crystal plates, and where the plurality of crystal plates are cooperatively configured to form a periodic structure that achieves quasi-phase-matching (QPM) of the first fundamental frequency and the second harmonic frequency.

A method for growing a periodically-poled nonlinear crystal is disclosed, in accordance with one or more embodiments of the present disclosure. In embodiments, the method includes placing a periodically-poled seed crystal in contact with a melt mixture from a platinum (Pt) nozzle connected to a Pt crucible containing melt mixture, where the periodically-poled seed crystal comprises at least one of strontium tetraborate (SBO) or lithium triborate (LBO), where the melt comprises at least one of a mixture of Sr, B, and O or a mixture of Li, B, and O. In embodiments, the method includes pulling the periodically-poled seed crystal away from the Pt nozzle at a predetermined velocity while maintaining contact with the melt until the periodically-poled nonlinear crystal forms.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1 is a simplified block diagram of an optical system, in accordance with one or more embodiments of the present disclosure.

FIG. 2 is a simplified block diagram depicting a laser assembly, in accordance with one or more embodiments of the present disclosure.

FIG. 3 is a simplified diagram depicting a furnace for growing periodically-poled strontium tetraborate (SBO), in accordance with one or more embodiments of the present disclosure.

FIG. 4A is a simplified diagram depicting a periodically-poled SBO seed crystal, in accordance with one or more embodiments of the present disclosure.

FIG. 4B is a simplified diagram depicting a periodically-poled SBO crystal, in accordance with one or more embodiments of the present disclosure.

FIG. 5 is a simplified diagram depicting a periodically-poled SBO crystal grown from a periodically-poled SBO seed, in accordance with one or more embodiments of the present disclosure.

FIG. 6 is a flowchart depicting a method for growing a periodically-poled nonlinear crystal, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to an improvement in nonlinear crystal growth of periodically-poled strontium tetraborate (SBO) (SrB₄O₇) and lithium triborate (LBO) (LiB₃O₅) for semiconductor optical systems.

SBO is a material that has gained increased interest for DUV frequency generation. The space group of SBO is Pnm2₁ space group and the point group is mm2, indicating that a non-zero d₃₃ nonlinear coefficient may exist and be utilized for quasi-phase matching. For SBO, the natural crystallographic coordinates are a=4.4255 Å, b=10.709 Å, and c=4.2341 Å (Oseledchik, Y. S. et al., “New nonlinear optical crystals: strontium and lead tetraborates”, Optical Materials 4, 669-674 (1995), which is herein incorporated by reference in the entirety). The crystallographic coordinates in a rectangular frame of reference are X, Y, and Z, and X, Y, Z correspond to a, b, c. The optical coordinates are x, y, and z, and x,-y, z correspond to b, a, c respectively. The z optical coordinate corresponding to the n_{z} index of refraction is along the 2₁ symmetry axis of SBO. In the case of quasi phase matching (QPM) of SBO, the alternating axis is the c-axis in order to access the high d₃₃ nonlinear coefficient. This d₃₃ nonlinear coefficient has been measured as 1.5 pm/V for 800 nm to 400 nm frequency doubling (Petrov, V., et al., “Application of the nonlinear crystal SrB₄O₇ for ultrafast diagnostics converting to wavelengths as short as 125 nm”, Optics Letters, 29, 4 (2004), which is herein incorporated by reference in the entirety). Further, SBO has DUV transparency for wavelengths as short as 125 nm, and frequency conversion to this wavelength has been shown. SBO has a UV light-induced damage threshold at 266 nm of 16.4 J/cm², significantly higher than that of calcium fluoride (CaF₂) (11.4 J/cm²) and silica (4.8 J/cm²) (Tanaka et al., “High surface laser-induced damage threshold of SBO single crystals under 266-nm (DUV) laser irradiation” Optics Express, 28, 20 29239 (2020), which is herein incorporated by reference in the entirety). While biaxial, SBO is nearly isotropic (Oseledchik, Y. S. et al., “New nonlinear optical crystals: strontium and lead tetraborates”, Optical Materials 4, 669-674 (1995)), and so birefringent phase matching is not possible for frequency conversion in the DUV. Because of the high d₃₃ nonlinear coefficient, SBO is a candidate for quasi-phase matching, in which the fundamental and second harmonic are polarized parallel to each other and parallel to the c-axis. The phase mismatch caused by the different index of the fundamental and higher harmonic is compensated by alternatively flipping the direction of the c crystal axis of the material by 180 degrees, so that the phase difference between the harmonics is alleviated by the different sign of the nonlinear coefficient.

It is noted that SBO exhibits unique optical and mechanical properties. The transparency range of SBO is 130-3200 nm in wavelength. See Y. S. Oseledchik, A. L. Prosvirnin, A. I. Pisarevskiy, V. V. Starshenko, V. V. Osadchuk, S. P. Belokrys, N. V. Svitanko, A. S. Korol, S. A. Krikunov, and A. F. Selevich, “New nonlinear optical crystals: strontium and lead tetraborates,” Opt. Mater. 4, 669 (1995), which is incorporated by reference herein in the entirety. This broad transparency range covers VUV, DUV, visible, and near infrared (IR) wavelength ranges. The VUV and DUV ranges are of particular interest to semiconductor inspection and metrology. It is also noted that the transmittance is high. For instance, the transmittance exceeds 80% from about 250 nm to about 2500 nm. This high transmittance makes SBO a good candidate for frequency generation especially for the UV wavelength range. If SBO is grown in optimal conditions, a better transmission curve can be obtained: the transmittance can reach more than 80% for wavelengths longer than 200 nm and more than 50% for 130 to 200 nm. Dielectric and optical properties of strontium tetraborate glasses are described by M. V. Shankar and K. B. R. Barma in “Dielectric and Optical Properties of strontium tetraborate Glass,” Journal of Materials Science Letters 15 (1996) 858-860, which is incorporated herein by reference in the entirety.

It is further contemplated herein that LBO is a well-studied and commercially available nonlinear optic material. LBO belongs to the Pna2₁ space group and mm2 point group, indicating that a d₃₁, d₃₂, d₃₃ d₂₄, and d₁₅, nonlinear coefficient may exist and could be used for quasi-phase matching. For LBO, following the convention of Roberts, D., in “Simplified characterization of uniaxial and biaxial nonlinear optical crystals: a plea for standardization of nomenclature and conventions”, IEEE Journal of quantum electronics, 28, 10 (1992), Table I “IEEE/ANSI” heading, which is incorporated herein by reference in the entirety, the natural crystallographic coordinates are a=7.3788 Å, b=8.4473 Å, and c=5.1395 Å. The crystallographic coordinates in a rectangular frame of reference are X, Y, and Z, and X, Y, Z correspond to a, b, c. The optical coordinates are x, y, and z, and x, y, z correspond to b, c, a respectively. The y optical coordinate corresponding to the ny index of refraction is along the 2₁ symmetry axis of LBO. In the case of QPM of LiB₃O₅, the alternating axis is the c-axis in order to access the high d₃₁ and dis nonlinear coefficients. The d₃₁, d₃₂, and d₃₃ nonlinear coefficients have been measured as 0.85 pm/V, −0.67 pm/V, and 0.04 pm/V, respectively, at 1064 nm (“Simplified Characterization of Uniaxial and Biaxial Nonlinear Optical Crystals: A Plea for Standardization of Nomenclature and Conventions”, Roberts, D. A., IEEE J. of Quantum Electron., 28, 10 (1992), which is incorporated herein by reference in the entirety). Assuming Kleinman symmetry and neglecting absorption, the d₂₄ nonlinear coefficient is equal to the d₃₂ nonlinear coefficient and the dis nonlinear coefficient is equal to the d₃₁ nonlinear coefficient. The transparency range of LBO is 160 nm-2300 nm, and has sufficient birefringence to perform phase-matched frequency conversion for wavelengths as short as approximately 266 nm. Birefringent phase-matching is not possible for wavelengths less than 200 nm, but quasi-phase matching can be used. The d₃₃ nonlinear coefficient is too small for efficient conversion in practice, but the d₃₁ and dis nonlinear coefficients are large enough for practical quasi-phase matching. For type I phase matching utilizing the d₃₁ nonlinear coefficient, the fundamental is polarized parallel to the a crystallographic axis and produces a second harmonic polarized parallel to the c crystallographic axis. For type Il phase matching utilizing the d₁₅ nonlinear coefficient, one or part of the fundamental beams is polarized parallel to the c crystallographic axis and one or part of the fundamental beams is polarized parallel to the a crystallographic axis, and produces a second harmonic polarized parallel to the a crystallographic axis. The phase mismatch caused by the different index of the fundamental(s) and higher harmonic is compensated by alternatively flipping the direction of the c crystal axis of the material by 180 degrees, so that the phase difference between the harmonics is alleviated by the different sign of the nonlinear coefficient. The damage threshold of LBO is approximately 18 J/cm² at 355 nm, which is higher than BBO.

Ferroelectric materials, such as periodically-poled lithium niobate (PPLN) or magnesium barium fluoride (MgBaF₂), can have their crystal axis flipped via application of a static electric field, allowing for straightforward engineering of a quasi-phase matched material. As stated before, MgBaF₂ has a small nonlinear coefficient, making it unsuitable for quasi-phase matching, and PPLN is not transparent in the DUV. SBO and LBO are not known to exhibit the ferroelectric effect along the c-axis, therefore, alternate methods must be used to quasi-phase-match SBO and LBO. For example, one method starts with a large single crystal of SBO, as generally discussed in U.S. Pat. No. 11,543,732, entitled “Frequency Conversion Using Stacking Strontium Tetraborate Plates”, issued on Jan. 3, 2023; U.S. Pat. No. 11,237,455, entitled “Frequency Conversion Using Stacked Strontium Tetraborate Plates”, issued on Feb. 1, 2022; U.S. Pat. No. 11,567,391, entitled “Frequency Conversion Using Interdigitated Nonlinear Crystal Gratings”, issued on Jan. 31, 2023; and U.S. Pat. No. 11,899,338, entitled “Deep Ultraviolet Laser Using Strontium Tetraborate for Frequency Conversion”, issued on Feb. 13, 2024, all of which are incorporated in their entirety by reference herein. This single crystal is polished or etched into thin slabs of the correct thickness for quasi-phase matching, and each slab oriented with flipped c-axis relative to one another with air gaps between each slab, or are optically contacted. Another method to create quasi-phase matched SBO uses the Czochralski method (Aleksandrovsky, A. S., Vyunishev, A. M., and Zaitsev, A. I., “Applications of Random Nonlinear Photonic Crystals Based on Strontium Tetraborate”, Crystals, 2, 1393-1409 (2012), which is incorporated by reference in the entirety). The c-axis of SBO naturally switched during Czochralski growth, as found by Aleksandrovsky et al. This study found it was difficult to control the period of each layer during the growth process, and explored generation with randomly spaced layers. Random quasi-phase matching will be less efficient than quasi-phase matching (except for the statistically unlikely cases when the randomly grown layer thicknesses are each exactly odd multiples of the coherence length), and will give unpredictable results that differ from crystal to crystal, which is undesirable in commercial lasers.

High quality and quantity SBO grown with the Kyropoulos method using a twin-type stirring blade has been demonstrated by Tanaka, Y. et al. “Kyropoulos growth of a 300 g SBO single crystal using a twin-type stirring blade”, Japanese Journal of Applied Physics 61, 075503 (2022), which is incorporated herein by reference in the entirety. Because at atmospheric pressure the phase of SBO exists in a small region of the phase diagram, careful control must be taken to grow stoichiometric SrB₄O₇. A six-zone resistance heater furnace for the Kyropoulos growth can be used, with growth carried out between 995-1005 degrees C. (e.g., 1002 degrees C.). With a twin-type stirring blade and 15 rpm rotation of the Pt crucible, a growth rate of between 0.1-5 mm/day has been recorded. By starting with a polished, optically contacted quasi-phase matched SBO seed crystal, Kyropoulos growth in a similar manner will propagate the crystal pattern of the seed crystal and result in a larger quasi-phase matched SBO crystal that can be diced and stacked to multiply the quasi-phase matched layers.

LBO can be grown in large boules with high quality with the high-temperature solution top-seeding method. The crystal can be grown by the flux method with a boron trioxide (B₂O₃) self-flux, but with an addition of molybdenum trioxide (MoO₃) to reduce the viscosity of the flux, crystals have been reported in the literature weighing up to 2 kg in size. Details of this growth method can be found in the literature, for example, by Hu, Z. G. et al in “Large LBO Crystal Growth at 2 kg-level,” J. Cryst. Growth, 335 (2011), which is incorporated herein by reference in the entirety.

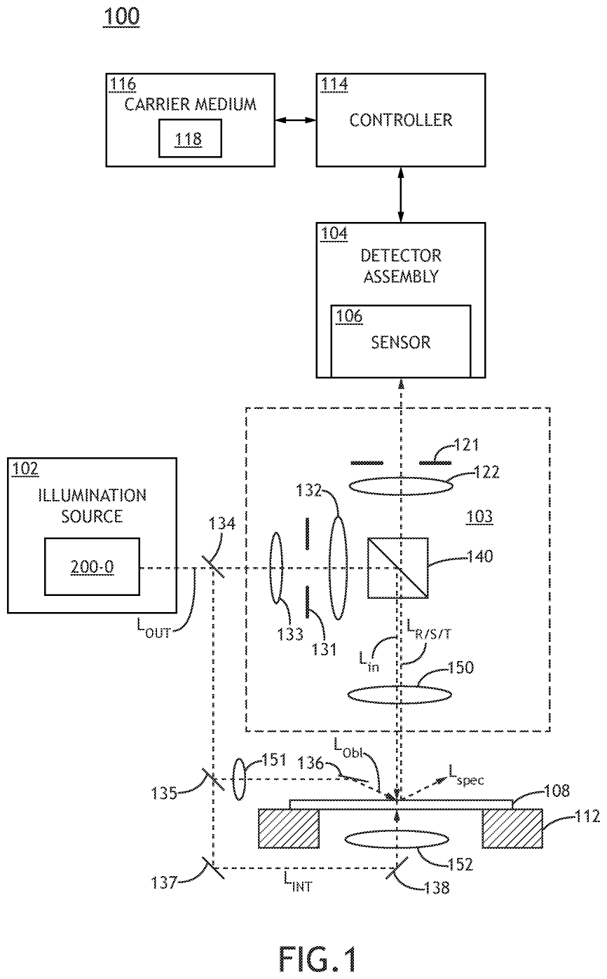

FIG. 1 illustrates a simplified block diagram of an optical system 100, in accordance with one or more embodiments of the present disclosure. The optical system 100 may be configured as an inspection system or a metrology system for inspecting a sample 108 and/or acquiring optical metrology measurements from the sample 108. The optical system 100 may include a semiconductor fabrication system. For example, the optical system 100 may include a fabrication system may be configured to cut, drill, or ablate material from sample 108, or to expose a pattern onto photoresist on sample 108.

The sample 108 may include any sample known in the art such as, but not limited to, a wafer, reticle, photomask, or the like. In embodiments, the sample 108 may be disposed on a stage assembly 112 to facilitate movement of the sample 108. The stage assembly 112 may include any stage assembly known in the art including, but not limited to, an X-Y stage, an R-θ stage, and the like. In embodiments, the stage assembly 112 is capable of adjusting the height of the sample 108 during inspection to maintain focus on the sample 108. In embodiments, a lens such as objective lens 150 may be moved up and down during inspection to maintain focus on the sample 108.

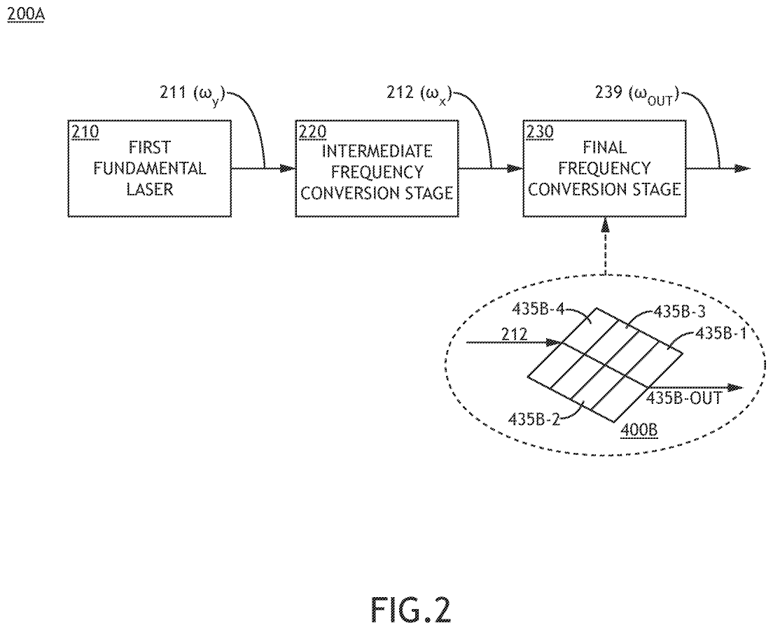

In embodiments, the optical system 100 includes an illumination source 102 that incorporates a laser 200-0 that generates output light L_{OUT} having an output frequency WOUT with a corresponding a wavelength in a range between approximately 120 nm and approximately 200 nm. Details of a laser 200-0 can be found in the description of FIG. 2 and Table 1. Laser 200-0 incorporates at least one of an SBO and an LBO quasi-phase matched crystal as grown using the methods described herein. Illumination source 102 may include additional light sources such as a laser operating at a longer or shorter wavelength or a broadband light source.

In embodiments, the optical system 100 includes one or more optical components such as, but not limited to, beam splitters, mirrors, lenses, apertures and waveplates that are configured to condition and direct light L_{OUT} to sample 108. The optical components may be configured to illuminate an area, a line, or a spot on sample 108. In embodiments, the beam splitter or mirror 134, mirrors 137 and 138 and lens 152 are configured to illuminate sample 108 from below so as to enable inspection or measurement of sample 108 by transmitting light LINT through the sample. In embodiments, beam splitters or mirrors 134 and 135, mirror 136 and lens 151 are configured to illuminate sample 108 with light at an oblique angle of incidence L_{Obl}, for example at an angle of incidence greater than 60° relative to a normal to the sample surface. In this embodiment, the specularly reflected light L_{Spec} may be blocked or discarded rather than collected. In embodiments, optics 103 are collectively configured to direct illumination light LIN to the top surface of sample 108.

When the sample 108 is illuminated in one or more of the above described modes, the optics 103 are also configured to collect light L_{R/S/T} reflected, scattered, diffracted, transmitted and/or emitted from the sample 108 and direct and focus the light L_{R/S/T} to sensor 106 of a detector assembly 104. It is noted herein that sensor 106 and the detector assembly 104 may include any sensor 106 known in the art. For example, the sensor 106 may include, but is not limited to, a charge-coupled device (CCD) detector, a complementary metal oxide semiconductor (CMOS) detector, a time-delay integration (TDI) detector, a photomultiplier tube (PMT), an avalanche photodiode (APD), a line sensor, an electron-bombarded line sensor, or the like. The detector assembly 104 may be communicatively coupled to a controller 114.

The controller 114 may be configured to store and/or analyze data from detector assembly 104 under control of program instructions 118 stored on carrier medium 116. The controller 114 may be further configured to control other elements of inspection system 100 such as stage assembly 112, illumination source 102 and optics 103.

In embodiments, the optics 103 includes an illumination tube lens 133. The illumination tube lens 132 may be configured to image an illumination pupil aperture 131 to a pupil within an objective lens 150. For example, the illumination tube lens 132 may be configured such that the illumination pupil aperture 131 and the pupil within the objective lens 150 are conjugate to one another. In embodiments, the illumination pupil aperture 131 may be configurable by switching different apertures into the location of illumination pupil aperture 131. In embodiments, the illumination pupil aperture 131 may be configurable by adjusting a diameter or shape of the opening of the illumination pupil aperture 131. In this regard, the sample 108 may be illuminated by different ranges of angles depending on the characterization (e.g., measurement or inspection) being performed under control of the controller 114. The illumination pupil aperture 131 may also include a polarizing element to control the polarization state of the illumination light LIN.

In embodiments, the one or more optical elements 103 include a collection tube lens 122. For example, the collection tube lens 122 may be configured to image the pupil within the objective lens 150 to a collection pupil aperture 121. For instance, the collection tube lens 122 may be configured such that the collection pupil aperture 121 and the pupil within the objective lens 150 are conjugate to one another. In embodiments, the collection pupil aperture 121 may be configurable by switching different apertures into the location of collection pupil aperture 121. In embodiments, the collection pupil aperture 121 may be configurable by adjusting a diameter or shape of the opening of collection pupil aperture 121. In this regard, different ranges of angles of illumination reflected or scattered from the sample 108 may be directed to detector assembly 104 under control of the controller 114. The collection pupil aperture 121 may also include a polarizing element so that a specific polarization of light L_{R/S/T} can be selected for transmission to sensor 106.

In embodiments, the illumination pupil aperture 131 and/or the collection pupil aperture 121 may include a programmable aperture. Programmable apertures are generally discussed in U.S. Pat. No. 9,255,887, entitled “2D programmable aperture mechanism,” to Brunner, issued on Feb. 9, 2016; and U.S. Pat. No. 9,645,287, entitled “Flexible optical aperture mechanisms,” to Brunner, issued on May 9, 2017, both of which are herein incorporated by reference in the entirety. Methods of selecting an aperture configuration for inspection are generally described in U.S. Pat. No. 9,709,510, entitled “Determining a configuration for an optical element positioned in a collection aperture during wafer inspection,” to Kolchin et al., issued on Jul. 18, 2017; and U.S. Pat. No. 9,726,617, entitled “Apparatus and methods for finding a best aperture and mode to enhance defect detection,” to Kolchin et al, issued on Aug. 8, 2017, both of which are herein incorporated by reference in the entirety.

The various optical elements and operating modes depicted in FIG. 1 are merely to illustrate how laser 200-0 may be used in inspection system 100 and are not intended to limit the scope of the present disclosure. A practical optical system 100 may implement a subset or a superset of the modes and optics depicted in FIG. 1. Additional optical elements and subsystems may be incorporated as needed for a specific application. The related references cited above, and the other references cited herein disclose many other important details of systems that may incorporate the laser 200-0.

FIG. 2 is a simplified block diagram depicting a laser assembly 200 configured to generate a wavelength in the range of approximately 120 nm to approximately 200 nm (e.g., approximately 193 nm) according to an embodiment of the present disclosure.

In embodiments, the laser assembly 200 includes a first fundamental laser 210 and two frequency conversion (doubling) stages (i.e., one intermediate frequency conversion (doubling) stage 220, and a final frequency conversion (doubling) stage 230) that are cooperatively configured to generate laser output light 239 having a wavelength in the range of approximately 120 nm to approximately 200 nm. The first fundamental laser 210 is configured to generate first fundamental light 211 having a first fundamental wavelength in the range of approximately 720 nm to approximately 800 nm and a corresponding first fundamental frequency wy. The first frequency conversion (doubling) stage 220 receives the first fundamental light 211 and generates second harmonic light 212 with a second harmonic frequency wx equal to twice the first fundamental frequency Wy. The final (second) frequency conversion (doubling) stage 230 receives the second harmonic light (intermediate frequency light) 212 and generates the laser output light 239 with an output frequency wour that is equal to four times the first fundamental frequency Wy.

Referring to FIG. 2, the first fundamental laser 210 is configured using any suitable technique to generate the first fundamental light 211 (or “fundamental”) at the first fundamental frequency wy. In embodiments, the first fundamental laser 210 is configured such that the first fundamental light 211 is generated at a first fundamental frequency Wy corresponding to a wavelength between approximately 720 nm and approximately 800 nm (such as a wavelength of approximately 774 nm). In embodiments, the first fundamental laser 210 is implemented using a titanium-sapphire (Ti-sapphire) lasing medium. In order to generate sufficient light at a wavelength of approximately 193 nm for inspecting semiconductor wafers, reticles or photomasks, it is contemplated herein that the first fundamental laser 210 should generate tens or hundreds of Watts of fundamental light 211. Other applications may not require so much power or may need more power. Depending on the pulse width and repetition rate requirements for laser 200, the first fundamental laser may be configured as a Q-switched laser, a mode-locked laser or a CW laser.

The first frequency conversion (doubling) stage 220 may be configured to generate second harmonic light 212 from the first fundamental light 211. In embodiments, the first frequency conversion (doubling) stage 220 incorporates a lithium triborate (LBO) nonlinear crystal configured for critical phase matching of the first fundamental frequency and the second harmonic frequency. The first frequency conversion (doubling) stage 220 may include other components as necessary, such as a prism for separating the second harmonic light 212 from unconsumed fundamental light. The first frequency conversion (doubling) stage 220 may include a cavity resonant at the first fundamental frequency to increase the conversion efficiency.

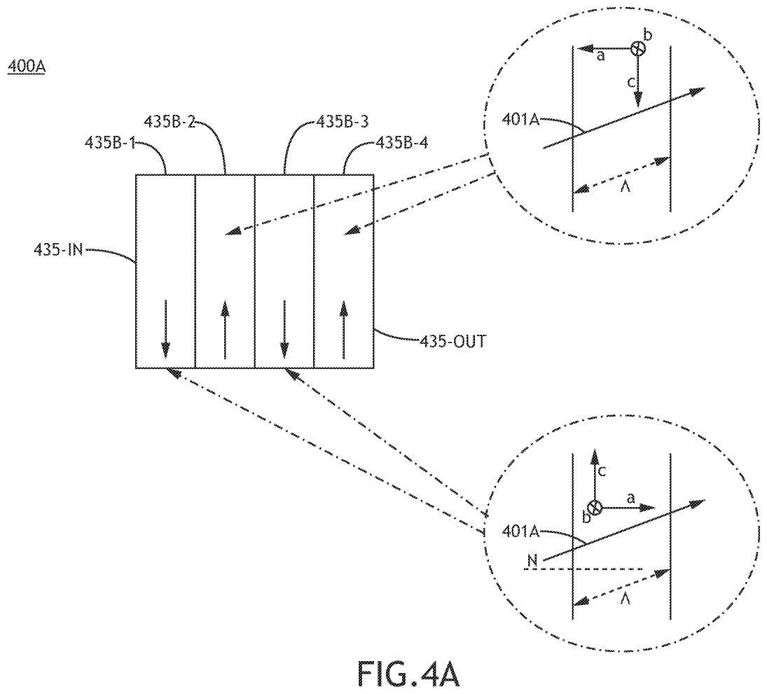

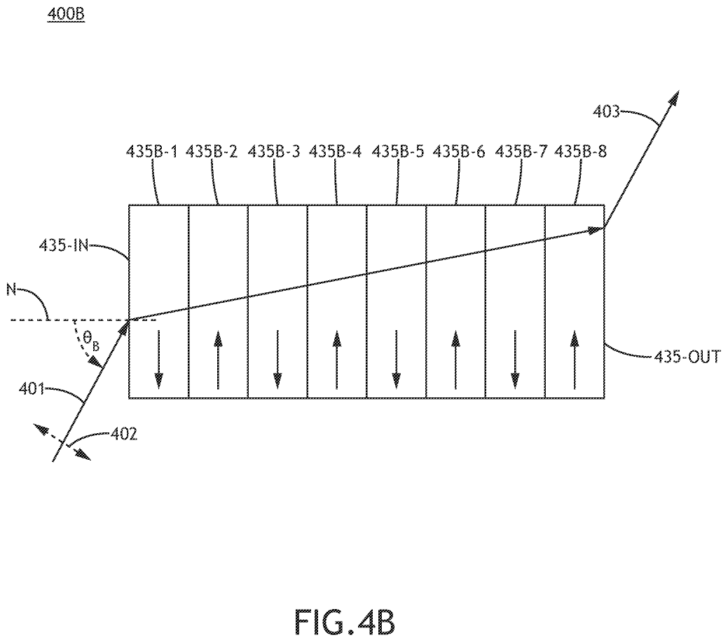

The final frequency conversion (doubling) stage 230 may be configured to generate laser output light 239 from the second harmonic light 212. The final frequency conversion (doubling) stage 230 may incorporate nonlinear crystal 400B configured to double the frequency of the second harmonic light 212, and to output light 435-OUT that includes light at the frequency of the laser output light 239 and unconsumed second harmonic light. The nonlinear crystal 400B may include a stack of SBO or LBO plates. It is noted herein that for purposes of illustration, FIG. 2 depicts four such plates, 435B-1, 435B-2, 435B-3 and 435B-4 stacked one on the other. However, it is noted herein that in a practical embodiment, there may be tens or hundreds or thousands of stacked plates. FIG. 2 depicts the plates as touching one another. The thickness of each plate is chosen to enable quasi-phase matching for doubling the frequency of the second harmonic light 212. Adjacent plates (such as plates 435B-1 and 435B-2) have their crystal c axes oriented in opposite directions relative to one another. These and other important aspects of the nonlinear crystal are described in detail below in relation to FIG. 4B.

The final frequency conversion (doubling) stage 230 may include other optical components as necessary, such as a prism for separating the laser output light 239 from unconsumed fundamental and second harmonic lights. The final frequency conversion (doubling) stage 230 may include a cavity to recirculate the second harmonic frequency to increase the conversion efficiency.

In embodiments, a single cavity may include both a first frequency doubling stage 220 and a final frequency doubling stage 230. In embodiments, the first fundamental laser 210 includes a laser with output frequency of approximately 1000 nm, such as 1064 nm or 1030 nm. In embodiments, the first frequency conversion stage 220 includes sum-frequency generation, sum-difference generation, optical parametric oscillation, or optical parametric amplification stages. In embodiments, the final frequency conversion stage 230 includes a sum-frequency generation stage with frequency conversion crystal 400B, as described further in the description of FIG. 4B. Frequency conversion paths are generally discussed in U.S. Pat. No. 11,543,732, entitled “Frequency Conversion Using Stacking strontium tetraborate Plates”, issued on Jan. 3, 2023; U.S. Pat. No. 11,237,455, entitled “Frequency Conversion Using Stacked strontium tetraborate Plates”, issued on Feb. 1, 2022; U.S. Pat. No. 11,567,391, entitled “Frequency Conversion Using Interdigitated Nonlinear Crystal Gratings”, issued on Jan. 31, 2023; and U.S. Pat. No. 11,899,338, entitled “Deep Ultraviolet Laser Using strontium tetraborate for Frequency Conversion”, issued on Feb. 13, 2024, all of which are incorporated in their entirety by reference herein.

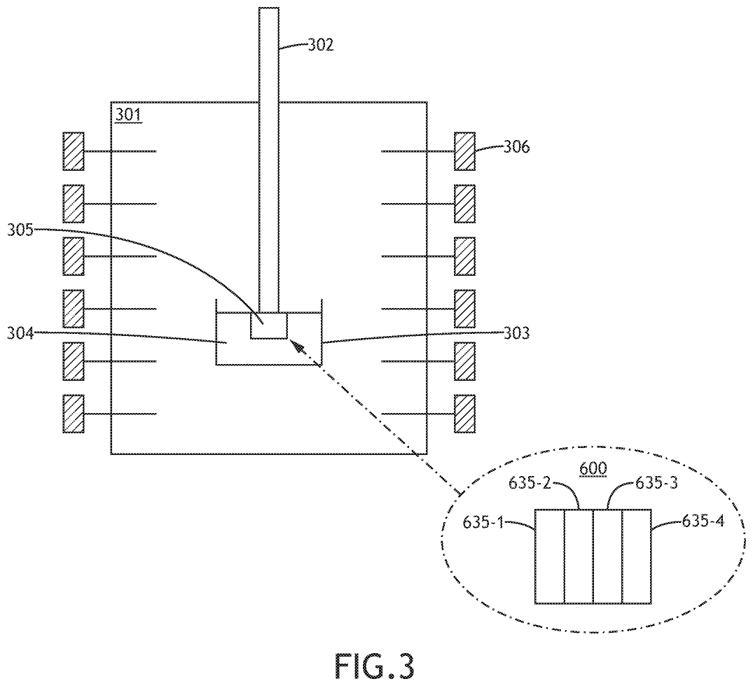

FIG. 3 is a simplified block diagram depicting a furnace 301 for growing SBO from a seed crystal 305 using the top seeded Kyropoulos method.

In embodiments, the furnace 301 may include a five-, six-, or more zone resistance heating furnaces, including a platinum crucible 303 with a diameter of about 150 mm and a height of about 150 mm. The platinum crucible 303 may be larger or smaller depending on the final size of the crystal grown, and should be about twice the diameter of the desired final crystal size. The seed crystal 305 may be fixed to alumina tube 302 to prevent the seed crystal 305 from falling into the melt 304, and also to provide cooling liquid or gas to the seed crystal 305 to prevent melting during growth. In embodiments, the melt 304 is composed of strontium carbonate (SrCO₃) and boron trioxide (B₂O₃) powders with boron trioxide as the self-flux with composition approximately 67% of the melt. L-shaped or twin-type stirring blades may be used to promote melt mixing. The melt 304 temperature should remain near 1000° C. and may be measured by one or more thermocouples 306, and crucible rotation should be about 10-20 rpm. It is noted that the seed crystal 305 is described further herein with respect to FIG. 4A.

Another method which can be used to grow a periodically-poled SBO crystal from a periodically-poled seed crystal is Hydrothermal growth. Hydrothermal growth of a single-crystal SBO has been demonstrated by Mcmillen, C., in “Hydrothermal Crystal Growth of Oxides for Optical Applications,” Dissertation, May 2007, Chapter 4, which is herein incorporated by reference in the entirety. SBO growth was demonstrated with an Sr:B ratio of 1:14.6. The mineralizer used was 1M sodium hydroxide (NaOH) at 565 C and 20 kpsi, and the boron was introduced in high densities via (NH₄)₂B₁₀O₁₆·8H₂O. A mineralizer comprising one or more of NaOH, sodium chloride (NaCl), strontium dichloride (SrCl₂), potassium chloride (KCl), strontium hydroxide (Sr(OH)₂), cesium fluoride (CsF), lithium chloride (LiCI), potassium hydroxide (KOH), LiOH, and water (H₂O) could alternatively be used (“Hydrothermal Crystal Growth of Metal Borates for Optical Applications” by Carla Heyward, Dissertation, August 2013, which is herein incorporated by reference in the entirety). Sr(OH)₂ was used as the strontium source. The SBO crystals in this thesis, grown without seed in 0.25 inch O.D. silver ampules, were up to 1.5 mm in size. A temperature gradient of 10-120° C. could be maintained across the autoclave and measured by means of thermocouples strapped to the outside.

Hydrothermal methods could eliminate problems caused by the high viscosity of B₂O₃ melts used with the Kyropoulos method to grow borate crystals, and avoid inclusions caused by additives such as MoOs used to reduce viscosity. 1-5 wt. % are ideal solubility values for hydrothermal growth of large crystals. Other sources could be used as feedstock for SBO hydrothermal growth, such as glassy crystals containing strontium and borate, Sr(OH)₂, B₂O₃, H₃BO₃, and SrCO₃ could be used.

Another method which may be used to grow a periodically poled SBO crystal from the periodically-poled seed crystal uses edge-defined film-fed growth (EFG) or the micro-pulling-down method. In EFG, a stoichiometric melt of SBO may be contained in a crucible made of platinum or another inert material and one end of a die or narrow tube may be submerged into the melt. Capillary action pulls the melt to the un-submerged end of the slit, die, or tube, where the melt contacts the surface of a periodically-poled SBO seed crystal. The seed crystal is slowly pulled away from the slit, die, or tube, and as the melt adjacent to the seed crystal cools, it crystalizes in the same periodically poled pattern as the seed crystal. The capillary forces continue to supply melt as the seed crystal is pulled away. In this way, the shape of the crystal can be controlled by the shape of the die or tube. This method is currently used to make high quality sapphire crystals. The micro-pulling-down method may use a periodically poled SBO or LBO seed crystal positioned below a nozzle connected to a crucible of stoichiometric melt at a controlled temperature. The nozzle and crucible may be made of platinum or another inert material. The seed crystal at a lower temperature than the melt makes contact with the drop of melt at the end of the nozzle, and the seed crystal is pulled downward at a controlled speed away from the nozzle. The melt touching the seed crystal cools and crystalizes in the same periodically-poled pattern as the seed crystal as it moves away from the nozzle. The nozzle replenishes the melt. The micro-pulling-down method has been demonstrated using a seed crystal of poled lithium tetraborate by Maeda, K. et al in “Fabrication of Quasi-Phase-Matching Structure during Paraelectric Borate Crystal Growth”, Applied Physics Express 6, 015501 (2013), which is herein incorporated by reference in the entirety. Single-crystal SBO has been grown using the micro-pulling-down method by Machida, T. et al. in Growth of Transparent SrB₄O₇ Crystal Fiber by the μ-PD Method “, Trans. Mater. Res. Soc. Jpn., 42, 123-126 (2017), which is herein incorporated by reference.

A periodically-poled LBO crystal can be grown with the high-temperature solution top-seeding method, using a periodically-poled LBO seed crystal, as discussed herein with respect to FIG. 4A. The crystal can be grown by the flux method with a B₂O₃ self-flux, or with an addition of MoOs to reduce the viscosity of the flux. Details of this growth method can be found in the literature, for example, by Hu, Z. G. et al in “Large LBO Crystal Growth at 2 kg-level,” J. Cryst. Growth, 335 (2011), which is incorporated by reference in the entirety.

In embodiments, other crystal growth methods, such as the Czochralski method, other pulling methods, or other flux or melt growth methods can be used.

FIG. 4B is a simplified block diagram depicting an SBO or LBO periodically-poled crystal. In particular, FIG. 4B depicts an embodiment in which nonlinear crystal 400B includes four stacked SBO or LBO plates 435B-1 to 435B-8 configured to double the frequency of input light 401 having a frequency wx. Although FIG. 4B illustrates nonlinear crystal 400B having a periodic structure including eight stacked SBO or LBO crystal plates 435B-1 to 435B-8, the total number of SBO or LBO plates may be as few as two, may be more than ten, or may be more than 100. There may be an odd or even number of plates. The thickness of each of the SBO or LBO plates 435B-1 to 435B-4 may be hundreds of nanometers to hundreds of microns. Concretely, the SBO or LBO plate thickness A in a propagation direction of the light 401A inside a crystal plate is given by:

$$Λ = {mL}_{c} , \qquad ( Equation 1 )$$

where m is an odd integer (e.g., 1,3,5,7 . . . ) and L_{c} is a quasi-phase-matching (QPM) critical length

$${L}_{c} = \frac{π}{Δ k} , \qquad ( Equation 2 )$$

where in the case of second harmonic generation, Δk is defined by

$$Δ k = k ( 2 {ω}_{x} ) - 2 k ( {ω}_{x} ) , \qquad ( Equation 3 )$$

and in the case of sum-frequency generation, Δk is defined by

$$Δ k = k ( {ω}_{3} ) - k ( {ω}_{1} ) - k ( {ω}_{2} ) , \qquad ( Equation 4 )$$

where k(ω) is the wavevector of light of frequency ω in nonlinear crystal 400B given by

$$k ( ω ) = \frac{ω n ( ω )}{c} , \qquad ( Equation 5 )$$

and where n(ω) is the refractive index of the nonlinear crystal for the appropriate polarization at frequency ω and c is the velocity of light in vacuum. In the case of sum-frequency generation, ω₁+ω₂=ω₃, where ω₃ is the frequency of the generated light.

In a non-limiting example, the crystal plate thickness and orientation of the plurality of crystal plates are configured to achieve phase matching to generate a wavelength of 193 nm. In an additional non-limiting example, the crystal plate thickness and orientation of the plurality of crystal plates are configured to achieve phase matching to generate a wavelength between 172-178 nm. In an additional non-limiting example, the crystal plate thickness and orientation of the plurality of crystal plates are configured to achieve phase matching to generate a wavelength between 147-153 nm. In an additional non-limiting example, the crystal plate thickness and orientation of the plurality of crystal plates are configured to achieve phase matching to generate a wavelength between 129-134 nm.

In a non-limiting example, the crystal plate thickness is an odd multiple of between at least one of: 700-860 nm, 435-620 nm, 510-690 nm, 200-380 nm, 200-320 nm, or 80-175 nm. In an additional non-limiting example, the crystal plate thickness is an odd multiple of between at least one of: 700-920 nm, 420-646 nm, and 460-730 nm.

For doubling the frequency of input light 401 having a wavelength of 386.8 nm, the quasi-phase-matching critical length L_{c} for SBO is about 0.85 μm (such as a thickness between 0.8 μm and 0.9 μm). In LiB₃O₅, the critical length, L., is about 0.9 μm for type I quasi-phase matching (386.8 nm light is polarized along the a crystallographic axis and 193.4 nm light is polarized along the c crystallographic axis) (such as a thickness between 0.85 μm and 0.95 μm). The critical length, L_{c}, is about 0.72 μm for type II quasi-phase matching (half of the 386.8 nm light is polarized along the a crystallographic axis and half is polarized along the c crystallographic axis, and 193.4 nm light is polarized along the c crystallographic axis) (such as a thickness between 0.7 μm and 0.8 μm). A reasonable m may be in a range from 1 to about 999 to achieve a convenient slab thickness for handling and processing. This exemplary QPM critical length for generating light having a wavelength of 193.4 nm by frequency-doubling light having a wavelength of 386.8 nm was calculated from the relevant refractive indices of SBO using the Sellmeier model published by P. Trabs, F. Noack, A. S. Aleksandrovsky, A. I. Zaitsev, N. V. Radionov, and V. Petrov, in “Spectral fringes in non-phase-matched SHG and refinement of dispersion relations in the VUV”, Opt. Express 23, 10091 (2015), and from the relevant refractive indices of LBO using the Sellmeier model published by K. Kato, in “Temperature-tuned 90° phase-matching properties of LiB₃O₅”, IEEE J. Quant. Electr. 30 (12), 2950-2952 (1994), which are all incorporated by reference in their entirety. The accuracy of these Sellmeier models is uncertain. Furthermore, varying levels of impurities in an SBO or LBO crystal or the presence of defects within a crystal may slightly change values of the refractive indices of that crystal. It is contemplated herein that one skilled in the relevant arts would understand how to calculate the QPM critical length using the above equations for specific input and output frequencies given accurate refractive indices of the crystal.

Referring to FIG. 4B, input light 401 of frequency ωₓ, which can be comprised of one or more wavelengths depending on whether second harmonic generation or sum frequency generation is desired, is incident on input surface 435-IN of nonlinear crystal 400B. The SBO or LBO plates 435B-1 to 435B-8 are optically contacted on top of one another so that input surface 435-IN and output surface 435-OUT are oriented at an angle θ_{B} relative to the propagation direction of input light 401 of frequency ωₓ. Small adjustments can be made to the orientation of nonlinear crystal 400B (i.e., small adjustments to incident angle θ) to adjust the path length of the light A in the SBO plates in order to more precisely achieve QPM when the thickness of the plates is not precisely the intended thickness due to manufacturing variability. Additionally, the temperature of the stack of slabs can be tuned, thereby shifting the temperature-dependent index of refraction and correcting thickness variation-dependent issues. The light 403 exiting the stack of SBO or LBO plates comprises the second harmonic of the input light at a frequency of 2ωₓ in the case of second harmonic generation and the sum of the two fundamental frequencies in the case of sum frequency generation, and unconsumed input light at a frequency (ies) of ωₓ. The seed crystal slabs will be optically contacted, minimizing reflection or scattering losses between each slab. The as-grown section of the crystal will be continuous and therefore not have reflection or scattering losses at the interfaces, as the indices will be matched.

In embodiments, the angle θ_{B}, as shown in FIG. 4B, is approximately the Brewster's angle so as to minimize reflection losses without using an antireflection coating. Brewster's angle in SBO is approximately equal to 60.3° with respect to the surface normal N for wavelengths near 386 nm polarized parallel to the c axis of an SBO crystal and is approximately equal to 61.9° with respect to the surface normal N for wavelengths near 193 nm with the same polarization direction. The polarization direction of the input light 401 into the SBO periodically-poled crystal is illustrated by the dashed-line-arrow 402. Reflection losses are low at any angle within a few degrees (such as within ±2°) of Brewster's angle, so there will be very low reflection losses for both the input light and the output light for any incident angle near 61°.

In embodiments, input light 401 of frequency ωₓ can be prism coupled into the stack. In one such embodiment, extra material from the growth process at either end of the stack can be cut to allow light to couple in at the Brewster's angle and then travel through unpoled material before reaching poled material.

In embodiments, an antireflection coating for input light 401 and output light 403 can be applied to input surface 435-IN and/or output surface 435-OUT to minimize reflections of the light frequencies involved in the conversion.

Referring to FIG. 4A, in order to create a periodic structure for quasi-phase matching for the seed crystal 400A, SBO or LBO plates 435B-1 to 435B-4 are placed with one rotated relative to the other such that their corresponding c crystal axes are inverted with respect to each other (as shown in the two insets of FIG. 4A, in the case of SBO). The surface normal N of the SBO plate of thickness A (where A is the spacing between poles in the crystal along the propagation direction of light 401A inside the crystal) and the propagation direction of light 401A inside the SBO plate are shown in the two insets. This physical arrangement of the crystal plates allows for quasi-phase matching. This may be considered as analogous to using PPLN (periodically-poled lithium niobate) for quasi-phase matching except that lithium niobate is a ferroelectric crystal and can be periodically-poled via application of an electric field. In contrast, SBO and LBO are not known to be ferroelectric along the c-axis, so the crystal plates need to be physically arranged to create a periodic structure for quasi-phase matching.

In embodiments, the crystal axes of SBO plates 435B-1 to 435B-4 are oriented such that light 401 propagating inside the SBO plates propagates substantially perpendicular to the c-axis with a polarization direction (electric field direction) of light 401A substantially parallel to the c-axis. This utilizes the largest nonlinear coefficient in SBO, d₃₃, and hence maximize conversion efficiency. In a preferred embodiment utilizing LBO, there is an additional constraint for LBO in that to access the largest nonlinear coefficient, d₃₁, the fundamental polarization direction of light should be substantially parallel to the a-axis in the case of type I phase matching, or parallel to the c- and a-axis in the case of type II phase matching, and the generated harmonic polarization should be substantially parallel to the c-axis for type I and for type II phase matching, in plates 435B-1 to 435B-4. Therefore, the LBO crystal plates must be cut perpendicular to the b-axis in the c-a plane. The SBO crystal, as the fundamental and generated frequencies both have polarizations substantially parallel to the c-axis, can be cut perpendicular to the a-axis in the c-b plane, perpendicular to the b-axis in the a-c plane, or at any angle as long as the c-axis is included in the plane. For example, in embodiments the crystal axes of SBO plate 435B-1 through 435B-4 may be oriented such that the light 401 direction of propagation is substantially parallel to the a-axis of the SBO crystal. In embodiments, the crystal axes may be oriented such that light 401A propagates parallel to the b-axis, or at some angle within an a-b plane of the crystal. In other words, the crystal axes depicted in the two insets in FIG. 4A may be rotated about the c-axis. If the input surface of SBO plate 435B-1 is oriented at Brewster's angle with respect to input light 401, then the direction of propagation of the light 401 within plates 435B-1 through 435B-4 will be approximately 29.7° relative to surface normal N, for a fundamental wavelength of approximately 386 nm.

It is contemplated herein that there are many ways to fabricate and assemble nonlinear seed crystal 400A. When only a few plates are needed for a laser (such as when high conversion efficiency is not required), polishing the plates to a desired thickness and then optically contacting them in an appropriate orientation may be convenient. When hundreds (or more) of plates are required to achieve the required conversion efficiency, other fabrication methods may be more convenient. For example, U.S. Pat. No. 11,567,391, entitled “Frequency Conversion Using Interdigitated Nonlinear Crystal Gratings” and filed Dec. 18, 2021, generally discusses interdigitated nonlinear crystal gratings and methods for fabricating the same, which is incorporated herein by reference in its entirety. SBO and LBO slabs may be etched at the correct orientation, removed from their substrate, and optically contacted.

Another method to fabricate a seed crystal is described by Maeda, K., et al. in “Fabrication of Quasi-Phase-Matching Structures during Paraelectric Borate Crystal Growth,” Applied Physics Express 6, 015501 (2013), which is incorporated herein by reference in its entirety. This method uses a thin crystal with two different, adjacent crystal domains. A platinum (Pt) wire melts a small portion of a crystal close to the size of the Pt wire in one domain, and the wire is pulled slowly until it touches the second domain, and then retreats back into the first domain. The melted material “behind” the wire will recrystallize into the second domain orientation, creating a second domain finger within the first domain. This process can be repeated to generate periodically spaced fingers with the correct spacing for quasi-phase-matching. This crystal can then be used as a seed crystal in a pulling, solution growth, melt growth, or hydrothermal method to grow a larger crystal.

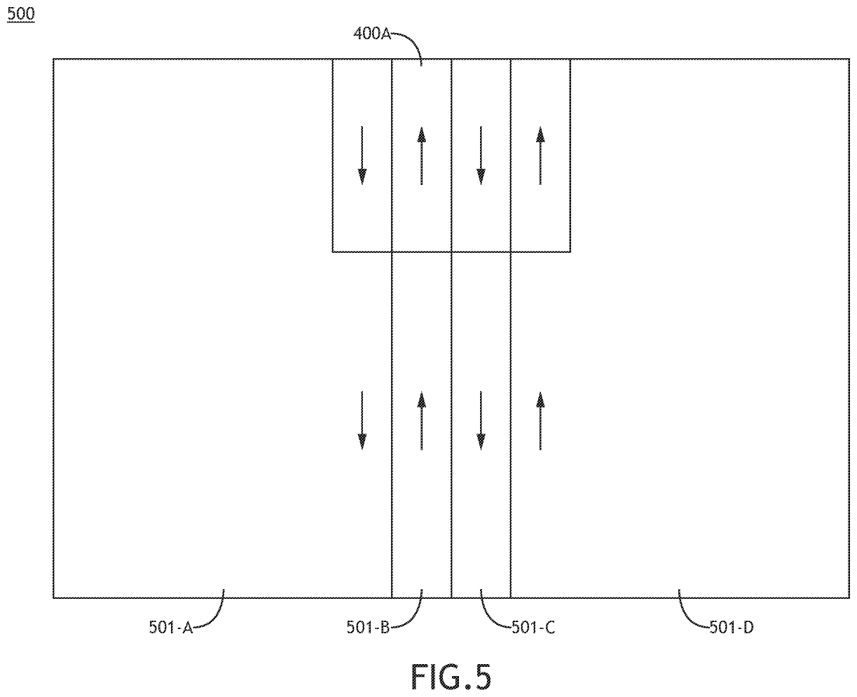

FIG. 5 depicts a final crystal 500 grown from a seed crystal 400A. In FIG. 5, only 4 slabs are shown in the seed crystal, but more slabs, between 2 and thousands can include the seed crystal. Once grown, the grown crystal 500 can be cut into a more desirable configuration by dicing the grown crystal parallel to the smallest dimension of each slab and stacking the slabs. In embodiments, the grown crystal 500 can be diced and stacked in other configurations. Grown crystal 500 that has been diced and stacked to create a crystal with more slabs 501-A, 501-B, 501-C, 501-D, then can be used as seed crystal 400A in further growths. Thus, a seed crystal can be iteratively grown, diced, stacked, and used as a seed crystal to make a grown crystal with thousands of periods for quasi-phase matching.

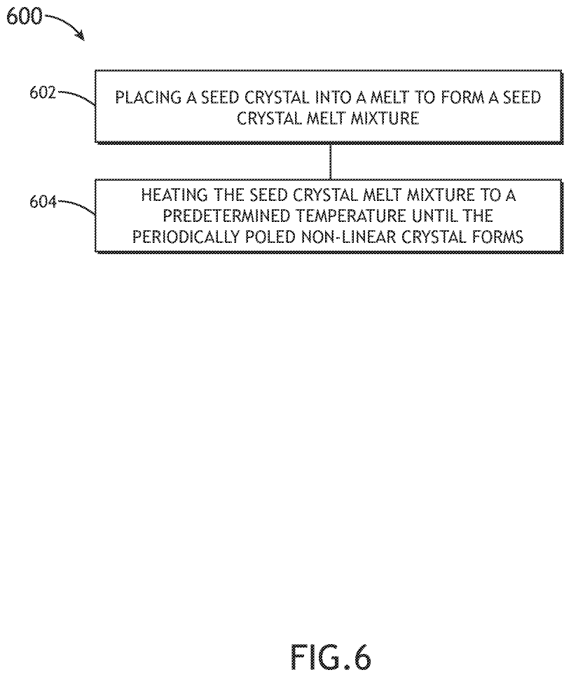

FIG. 6 is a flowchart depicting a method 600 for growing a periodically-poled nonlinear crystal. At step 602, a seed crystal may be placed into a melt to form a seed crystal melt mixture, where the seed crystal comprises at least one of strontium (SBO) or lithium triborate (LBO), where the melt comprises at least one of a mixture of Sr, B, and O or a mixture of Li, B, and O. At step 604, the seed crystal melt mixture may be heated and cooled to predetermined temperatures until the periodically-poled nonlinear crystal forms, as shown in FIG. 5.

Table 1 includes a table of exemplary coherence lengths needed in quasi-phase matched SBO or LBO crystals for wavelengths generated by the laser assemblies 200-0 and 200A of FIGS. 1 and 2 to generate laser output light L_{OUT} and 239 with wavelength approximately in the range of 125 nm to 140 nm (e.g., approximately 133 nm), 147 nm to 155 nm (e.g., approximately 152 nm), laser output light 161 with wavelength approximately in the range of 170 nm to 180 nm (e.g., approximately 177 nm), and with wavelength approximately in the range of 190 nm to 195 nm (e.g., approximately 193 nm), in accordance with exemplary embodiments of the present disclosure. For the fundamental laser type, an exemplary fundamental wavelength is shown, along with the wavelengths corresponding to the harmonics. The exact wavelength of a fundamental laser depends on many factors including the exact composition of the lasing medium, the operating temperature of the lasing medium, and the design of the optical cavity. Two lasers using the same laser line of a given lasing medium may operate at wavelengths that differ by a few tenths of 1 nm or a few nm due to the aforementioned and other factors. One skilled in the appropriate arts would understand how to choose the appropriate first and second fundamental wavelengths in order to generate the desired output wavelength from any fundamental wavelength close to those listed in the table. Similarly, if the desired output wavelength differs from 133 nm by a few nm, 152 nm by a few nm, from 177 nm by a few nm, or from 193 nm by a few nm, the desired output wavelength can also be achieved by an appropriate adjustment of the wavelength for the first or the second fundamental wavelength.

TABLE 1

| | | | LiB₃O₅ | LiB₃O₅ |
|---|---|---|---|---|
| | | | Coherence | Coherence |
| | | | length | length |
| Fundamental | Higher | SrB₄O₇ | (Type I | (Type II |
| wavelength(s) | harmonic | Coherence | phase- | phase- |
| (ωₓ or ω₁ and | wavelength | length | matching) | matching) |
| ω₂) | (2ωₓ or ω3) | (L_{c}) | (L_{c}) | (L_{c}) |
| 386 nm | 193 nm | 843 nm | 900 nm | 720 nm |
| 355 nm | 177 nm | 598 nm | 621 nm | 516 nm |
| 532 nm, | 177 nm | 655 nm | 690 nm | 573 nm or |
| 266 nm | | | | 552 nm |
| 532 nm, | 152 nm | 338 nm | | |
| 213 nm | | | | |
| 355 nm, | 152 nm | 297 nm | | |
| 266 nm | | | | |
| 266 nm | 133 nm | 134 nm | | |

Although the present disclosure is described herein using various fundamental wavelengths that facilitate generating laser output light at a desired wavelength between approximately 120-200 nm, other wavelengths within a few or a few tens of nanometers of this desired wavelength can be generated by changing the wavelength of the first fundamental laser (i.e., laser assembly 200A). Unless otherwise specified in the appended claims, such lasers and systems utilizing such lasers are considered within the scope of this disclosure.

Lasers with a wavelength in the sub-200 nm are not commercially available at sufficient power level or are unreliable or expensive to operate. Periodically-poled SBO and LBO crystals are not commercially available. In particular, there is no prior art for growing periodically-poled crystals with high purity, high damage threshold, high nonlinear coefficient, and high transparency in the sub-200 nm region from a periodically-poled seed.

Lasers with a wavelength in the sub-200 nm are not commercially available at sufficient power level or are unreliable or expensive to operate. There is no prior art other than excimer lasers for generating 1 W of light power or more in a wavelength range between approximately 120 nm and 200 nm with a multi-month lifetime. The embodiments of the present disclosure generate a wavelength between 120-200 nm, therefore providing better sensitivity for detecting small particles and defects than longer wavelengths. The lasers of the present disclosure do not use toxic or corrosive gasses and are therefore easier and less expensive to operate and maintain.

One skilled in the appropriate arts will readily appreciate that there are many possible applications of the laser crystals described herein in addition to their use in semiconductor inspection and metrology. For example, a laser operating at a wavelength close to 193.4 nm can be used in a lithography system configured to expose patterns into photoresist coated on a substrate such as a semiconductor wafer. In another example, a laser operating at a wavelength between about 120 nm and 200 nm may be used in a system configured to cut or ablate biological tissue. The lasers described herein can be configured to generate very short pulses at the output wavelength, which can enable preferential removal of material by ablation instead of by heating thereby causing less damage to surrounding material. For example, such lasers may be used in laser eye surgery or laser vision correction. Although the present disclosure has been described with respect to certain specific embodiments, it will be clear to those skilled in the art that the features of the present disclosure are applicable to other embodiments as well, all of which are intended to fall within the scope of the present disclosure.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the disclosure is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to disclosures containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the disclosure is defined by the appended claims.

What is claimed:

1. A method for growing a periodically-poled nonlinear crystal comprising:
placing a periodically-poled seed crystal into a melt to form a seed crystal melt mixture, wherein the seed crystal comprises at least one of strontium tetraborate (SBO) or lithium triborate (LBO), wherein the melt comprises at least one of a mixture of Sr, B, and O or a mixture of Li, B, and O; and
heating and cooling the seed crystal melt mixture to one or more predetermined temperatures until the periodically-poled nonlinear crystal forms.

2. The method of claim 1, wherein the melt is contained within a platinum crucible of a furnace, wherein the seed crystal is fixed to an alumina tube.

3. The method of claim 2, wherein the melt includes strontium carbonate and boron trioxide.

4. The method of claim 3, wherein the predetermined temperature is between 995-1005° C.

5. The method of claim 3, wherein the boron trioxide acts as a self-flux and makes up 67% of the melt.

6. The method of claim 1, wherein the melt comprises strontium hydroxide.

7. The method of claim 1, wherein the melt comprises:
at least one of boron oxide self-flux or molybdenum trioxide.

8. The method of claim 1, further comprising:
polishing thin slabs of crystal; and
forming the periodically-poled crystal by contacting the polished thin slabs together with alternative c-axis orientations,
wherein the thin slabs of crystal include at least one of strontium tetraborate or lithium triborate.

9. A periodically-poled nonlinear seed crystal comprising:
a plurality of crystal plates disposed in a stacked configuration, wherein the plurality of crystal plates include at least a first crystal plate and a second crystal plate, wherein the first crystal plate is adjacent to the second crystal plate,
wherein the plurality of crystal plates include at least one of one or more strontium tetraborate (SBO) plates or one or more lithium triborate (LBO) plates,
wherein the plurality of crystal plates are configured to form a periodic structure, wherein the periodic structure achieves quasi-phase-matching (QPM) of light.

10. The crystal of claim 9, wherein a first crystal axis of the first crystal plate is inverted with respect to a second crystal axis of the second crystal plate.

11. The crystal of claim 9, wherein a crystal plate thickness and orientation of the plurality of crystal plates are configured to achieve phase matching to generate a wavelength of 193 nm.

12. The crystal of claim 9, wherein a crystal plate thickness and orientation of the plurality of crystal plates are configured to achieve phase matching to generate wavelength between 172-178 nm.

13. The crystal of claim 9, wherein a crystal plate thickness and orientation of the plurality of crystal plates are configured to achieve phase matching to generate a wavelength between 147-153 nm.

14. The crystal of claim 9, wherein a crystal plate thickness and orientation of the plurality of crystal plates are configured to achieve phase matching to generate wavelength between 129-134 nm.

15. The crystal of claim 9, wherein a crystal plate thickness is an odd multiple of between at least one of:
700-860 nm, 435-620 nm, 510-690 nm, 200-380 nm, 200-320 nm, or 80-175 nm,
wherein a c crystal axis of the first crystal plate is inverted with respect to a c crystal axis of the second crystal plate.

16. The crystal of claim 9, wherein a crystal plate thickness is an odd multiple between at least of:
700-920 nm, 420-646 nm, and 460-730 nm,
wherein a c crystal axis of the first crystal plate is inverted with respect to a c crystal axis of the second crystal plate.

17. An optical system comprising:
an illumination source configured to generate illumination having a wavelength between 120 nm and 200 nm; and
an optical sub-system configured to direct the illumination from the illumination source onto a sample,
wherein the illumination source comprises:
a first fundamental laser configured to generate a fundamental laser beam having a corresponding fundamental frequency and a fundamental wavelength between 720 nm and 800 nm; and
two or more frequency doubling stages, the two or more frequency doubling stages including at least a intermediate frequency doubling stage and a final frequency doubling stage, the intermediate frequency doubling stage is configured to receive the first fundamental frequency and generate a second harmonic light having a second harmonic frequency, the final frequency doubling stage is configured to generate laser output light from the second harmonic light, the final frequency doubling stage includes a nonlinear crystal configured to double a frequency of the second harmonic light,
wherein the nonlinear crystal includes a plurality of crystal plates disposed in a stacked configuration such that each first SBO crystal plate is adjacent to at least one second crystal plate, the plurality of crystal plates includes at least one of one or more strontium tetraborate (SBO) crystal plates or one or more lithium triborate (LBO) crystal plates, and
wherein the plurality of crystal plates are cooperatively configured to form a periodic structure that achieves quasi-phase-matching (QPM) of the first fundamental frequency and the second harmonic frequency.

18. A laser assembly comprising:
a first fundamental laser configured to generate a fundamental laser beam having a corresponding fundamental frequency and a fundamental wavelength between 720 nm and 800 nm; and
two or more frequency doubling stages, the two or more frequency doubling stages including at least a intermediate frequency doubling stage and a final frequency doubling stage, the intermediate frequency doubling stage is configured to receive the first fundamental frequency and generate a second harmonic light having a second harmonic frequency, the final frequency doubling stage is configured to generate laser output light from the second harmonic light, the final frequency doubling stage includes a nonlinear crystal configured to double a frequency of the second harmonic light,
wherein the nonlinear crystal includes a plurality of crystal plates disposed in a stacked configuration such that each first SBO crystal plate is adjacent to at least one second crystal plate, the plurality of crystal plates includes at least one of one or more strontium tetraborate (SBO) crystal plates or one or more lithium Triborate (LBO) crystal plates, and
wherein the plurality of crystal plates are cooperatively configured to form a periodic structure that achieves quasi-phase-matching (QPM) of the first fundamental frequency and the second harmonic frequency.

19. A method for growing a periodically-poled nonlinear crystal comprising:
placing a periodically-poled seed crystal in contact with a melt mixture from a platinum (Pt) nozzle connected to a Pt crucible containing melt mixture, wherein the periodically-poled seed crystal comprises at least one of strontium tetraborate (SBO) or lithium triborate (LBO), wherein the melt comprises at least one of a mixture of Sr, B, and O or a mixture of Li, B, and O; and
pulling the periodically-poled seed crystal away from the Pt nozzle at a predetermined velocity while maintaining contact with the melt until the periodically-poled nonlinear crystal forms.

20. The method of claim 19, wherein the melt is contained within a platinum crucible of a furnace, wherein the melt is maintained at a predetermined temperature.

21. The method of claim 20, wherein the predetermined temperature is 995-1005° C.

22. The method of claim 19, wherein the melt comprises stoichiometric Sr, B, and O.

23. The method of claim 19, wherein the melt comprises stoichiometric Li, B, and O.

24. The method of claim 19, wherein the nozzle comprises a narrow tube, slit, or die, wherein capillary action transports melt from the Pt crucible to the seed crystal.
